(19) United States
(12) Patent Application Publication
(10) Pub. No.: US 2013/0019929 A1
(43) Pub. Date: Jan. 24, 2013

(54) REDUCTION OF LIGHT INDUCED DEGRADATION BY MINIMIZING BAND OFFSET

(71) Applicants: Ahmed Abou-Kandil, ELMSFORD, NY (US); Augustin J. Hong, WHITE PLAINS, NY (US); Jeehwan Kim, LOS ANGELES, CA (US); Mohamed Saad, WHITE PLAINS, NY (US); Devendra K. Sadana, PLEASANTVILLE, NY (US)

(72) Inventors: Ahmed Abou-Kandil, ELMSFORD, NY (US); Augustin J. Hong, WHITE PLAINS, NY (US); Jeehwan Kim, LOS ANGELES, CA (US); Mohamed Saad, WHITE PLAINS, NY (US); Devendra K. Sadana, PLEASANTVILLE, NY (US)

(73) Assignee: INTERNATIONAL BUSINESS MACHINES, ARMONK, NY (US)

(21) Appl. No.: 13/185,860

(22) Filed: Jul. 19, 2011

(51) Int. Cl. H01L 31/105; H01L 31/18

(52) U.S. Cl. 136/255; 438/87; 257/E31.061

(57) ABSTRACT

A device and method for reducing degradation in a photovoltaic device includes adjusting a band offset of the device during one or more of forming an electrode, forming a first doped layer or forming an intrinsic layer. The adjusting reduces a band offset between one or more of the electrode, the first doped layer and the intrinsic layer to reduce light-induced degradation of the device. A second doped layer is formed on the intrinsic layer.

### BACKGROUND

1. Technical Field

The present invention relates to photovoltaic devices and methods for fabrication, and more particularly to devices, structures and fabrication methods that reduce light-induced degradation by material selection and by adjusting band offsets.

2. Description of the Related Art

Solar devices employ photovoltaic cells to generate current flow. Photons in sunlight hit a solar cell or panel and are absorbed by semiconducting materials, such as silicon. Carriers gain energy allowing them to flow through the material to produce electricity. The solar cell converts the solar energy into a usable amount of electricity.

When a photon hits a piece of silicon, the photon may be transmitted through the silicon, the photon can reflect off the surface, or the photon can be absorbed by the silicon, if the photon energy is higher than the silicon band gap value. This generates an electron-hole pair and sometimes heat, depending on the band structure.

When a photon is absorbed, its energy is given to a carrier in light absorbing materials. Electrons in the valence band may be excited into the conduction band, where they are free to move within the semiconductor. The bond that the electron(s) were a part of forms a hole. These holes can move through the lattice creating mobile electron-hole pairs.

A photon need only have greater energy than that of a band gap to excite an electron from the valence band into the conduction band. Since solar radiation is composed of photons with energies greater than the band gap of silicon, the higher energy photons will be absorbed by the solar cell, with some of the energy (above the band gap) being turned into heat rather than into usable electrical energy.

When a hydrogenated amorphous silicon solar cell (a-Si:H) is soaked in solar radiation, efficiency of the cell is degraded as soaking time increases. Such phenomenon has not been observed for other types of solar cells. This is called the Staebler-Wronski effect. According to conventional theory of the Staebler-Wronski effect (SW effect), hydrogen (or other materials) is reconfigured reducing hydrogen passivation of silicon base materials of the solar cell under photon illumination. The solar cell experiences reduced fill factor (FF) and reduced open circuit voltage (V_{oc} both of which reduce the efficiency of the solar device.

A barrier height is a difference between a potential at the surface of a semiconductor and in the bulk of the semiconductor. The barrier height is affected by the type of material with which the semiconductor is in contact. A band offset is the measure of misalignment between energy levels at the interface between two solids. The offset between an electrode and a semiconductor is called a “Schottky barrier”. These quantities are measures of how much a given material resists the flow of electrical charge through a medium. These quantities are negatively affected in solar cells by light induced cell degradation. Both semiconductor-semiconductor band offset and semiconductor-electrode Schottky barrier increase the SW effect.

### SUMMARY

A device and method for reducing degradation in a photovoltaic device includes adjusting a band offset of the device during one or more of forming an electrode, forming a first doped layer or forming an intrinsic layer. The adjusting reduces a band offset between one or more of the electrode, the first doped layer and the intrinsic layer to reduce light-induced degradation of the device. A second doped layer is formed on the intrinsic layer.

A method for reducing degradation in a photovoltaic device includes forming a bi-layer electrode by providing different dopant concentrations of the bi-layer electrode relative to a first doped layer to be formed thereon such that the bi-layer has a lower dopant concentration in contact with the first doped layer than other portions of the bi-layer electrode to reduce band offset between the bi-layer electrode and the first doped layer; forming the first doped layer and an intrinsic layer on the first doped layer while adjusting a band offset between layers by adjusting dopant types and concentrations in at least one of the first doped layer and the intrinsic layer, such that light induced degradation is reduced with lower band offset between one or more of the bi-layer electrode, the first doped layer and the intrinsic layer; and forming a second doped layer.

A device having resistance to light-induced degradation includes a p-i-n stack having a p-type layer, an intrinsic layer and an n-type layer. A bi-layer transparent electrode in contact with the p-type layer has a doping gradient which increases with distance from an interface between the p-type layer and the bi-layer transparent electrode. The bi-layer transparent electrode providing an interface having a reduced barrier offset to provide resistance to light-induced degradation.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1A is a cross-sectional view of an a-Si:H p-i-n structure and an example of a source of band offset at a p-type layer to intrinsic layer (p-i) interface by varying Ge content at the intrinsic layer, and includes a graph of band gap versus atomic percent Ge in an intrinsic layer of the a-Si:H solar cell in accordance with the present principles;

FIG. 1B is a cross-sectional view of an a-Si:H p-i-n structure and an example of source of band offset at a p-i interface by varying C content at the p-type layer, and includes a graph of band gap versus percent C₃H₆ in SiH₄ in a p+ doped layer of the a-Si:H solar cell in accordance with the present principles;

FIG. 1C is a cross-sectional view of an a-Si:H p-i-n structure as an example of a source of band offset at a p-i interface by varying p-type layer deposition temperature and includes a graph of band gap versus deposition temperature of a p+ doped layer of the a-Si:H solar cell in accordance with the present principles;

FIG. 2 is a graph showing a relationship between efficiency change versus p-i band offset created by the methods presented in FIGS. 1A-1C in accordance with the present principles;

FIG. 3 is a graph showing efficiency of an a-Si:H solar cell before and after light soaking for 32 hours at 1.5 suns versus p-i band offset in accordance with the present principles;

FIG. 4 is a graph showing percent efficiency change (%) versus carrier concentration for transparent conductive oxide electrodes with different dopant concentrations in accordance with the present principles;

FIG. 5 is a photovoltaic device structure having a bi-layer electrode formed by a process which improves band offset in accordance with the present principles; and

FIG. 6 is a block/flow diagram showing a method for forming a photovoltaic device structure having improved band offset in accordance with one illustrative embodiment.

### DETAILED DESCRIPTION OF PREFERRED EMBODIMENTS

In accordance with the present principles, methods and devices are presented that provide light induced degradation resistance. Light induced degradation occurs in a semiconductor structure when the structure becomes saturated by incoming radiation (light soaked). The structure begins to degrade due in part to the reconfiguration of hydrogen atoms, which results in passivation and bond breaking between constituent materials. This degradation process becomes prominent if there exists a band offset at a p-i interface and/or at a transparent conductive oxide (TCO) to p+ interface—as discovered by the present inventors. This new mechanism is addressed in view of the Staebler-Wronski effect (SW effect) to provide improved solar devices. Based on this understanding, strategies for minimizing the SW effect are introduced.

Band offset at the p-i interface cannot be avoided since high band gap materials are required for the p+ layer whereas low band gap materials are desirable for an intrinsic layer to utilize more of the photon spectrum. Band offset at the TCO/p+ layer is also unavoidable since all developed TCO films are n-type. Therefore, it should be emphasized that there exists an offset amount between increased initial efficiency and reduced light induced degradation.

In particularly useful embodiments, photovoltaic devices are constructed using materials and processes that reduce the risk of light-induced degradation. In one example, a device is provided which has a minimized band offset at a p-doped layer to intrinsic layer (p-i) interface. In another example, material selection is performed for at least the p-i layers such that barrier height is minimized. In addition, materials are deposited using processes that are favorable to reduce barrier height and barrier offset. Combinations of these features are also contemplated.

It is to be understood that the present invention will be described in terms of a given illustrative architecture having a substrate; however, other architectures, structures, substrate materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

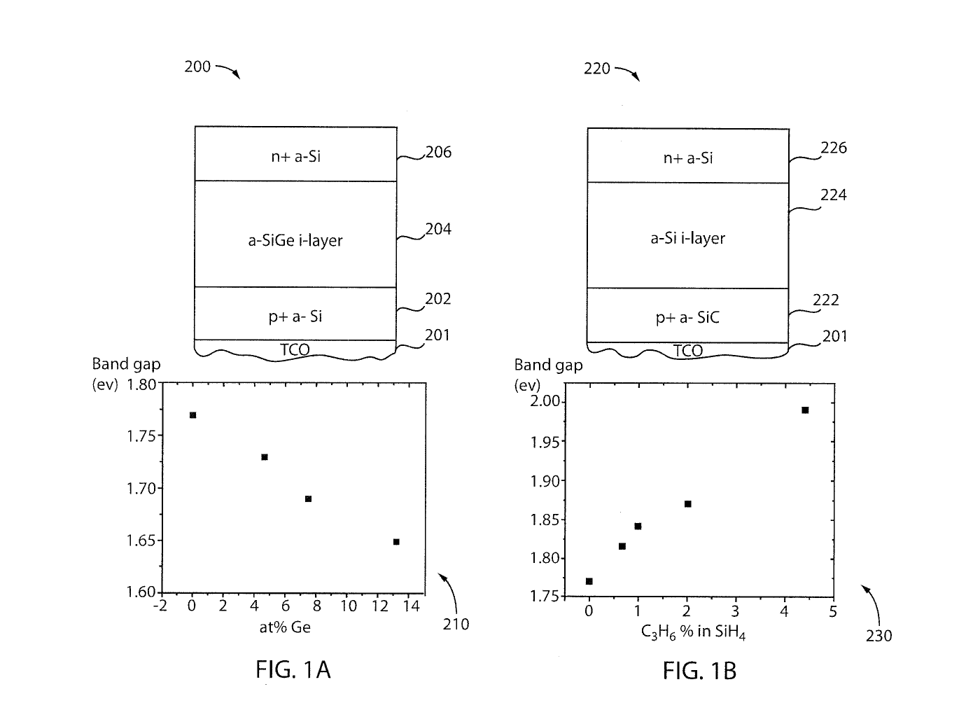

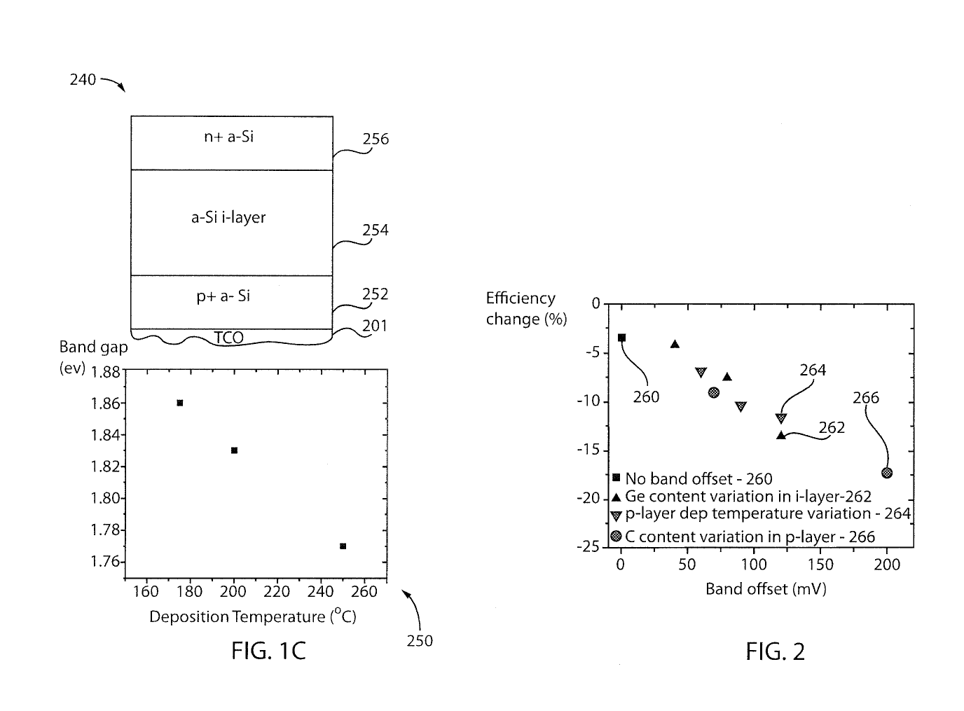

Referring now to the drawings in which like numerals represent the same or similar elements and initially to FIG. 1A, an illustrative structure 200 and accompanying graph 210 showing band gap (eV) versus atomic percent (at %) of Ge included in an intrinsic layer 204 is shown. The intrinsic layer 204 is disposed between a p+ doped layer 202 and an n+ doped layer 206. Layers 202 and 206 include a-Si in this example. In this method, Ge is added to the intrinsic layer 204 to provide a negative band offset. As shown in graph 210, the band offset decreases with added atomic percent or Ge in the intrinsic layer 204. With atomic percent changing from 0 to about 13% a band offset of, e.g., about 120 meV can be achieved. A transparent conductive oxide (TCO) electrode 201 may be provided.

Referring to FIG. 1B, an illustrative structure 220 and accompanying graph 230 showing band gap (eV) versus percent C₃H₆ in SiH₄ (C %) included in a p-type layer 222 is shown. The p-type layer 222 includes carbon and is comprised of amorphous silicon carbide (a-SiC). An intrinsic layer 224 and n+ doped layer 226 are included. The increased presence of C in p-type layer 222 provides a more positive band offset. As shown in graph 230, the band offset increases with added C content in the p-type layer 222. With percent changing from 0 to about 5%, a band offset of, e.g., about 220 meV can be achieved.

Referring to FIG. 1C, an illustrative structure 240 and accompanying graph 250 showing band gap (eV) versus deposition temperature (degrees C.) for the p-type layer 252 is shown. An intrinsic layer 254 is formed on the p+ doped layer 252 and an n+ doped layer 256. Layers 254, 252 and 256 include a-Si in this example. In this method, the p-type layer 252 is formed using a deposition temperature that is selected to provide a negative band offset. As shown in graph 250, the band offset decreases with increased deposition temperature. Therefore, lowering the deposition temperature from, e.g., 250 degrees C. to about 170 degrees C. could increase the band offset by, e.g., about 90 meV.

In accordance with a study performed by the inventors, efficiency degradation increases with p-i band offset. In other words, the larger the band offset between p-i layers (or p/TCO layers) the more likely degradation will occur and the degradation will be more significant. Efficiency change (%) versus p-i band offset is shown in FIG. 2.

Referring to FIG. 2, a plot 260 of no band offset, a plot 262 of Ge content variation in the intrinsic layer (204 of FIG. 1A), a plot 264 of p-layer (252 in FIG. 1C) deposition temperature variation and a plot 266 of C content variation in p-layer (222 of FIG. 1B) are illustratively depicted. Regardless of the methods used to create band offset, efficiency degradation increases with offset increase. As shown in FIGS. 1B and 1C, it is desirable that the p+ layer 222 or 252 has a higher band gap than the respective intrinsic layer 224 or 254 so that the initial efficiency can increase due to enhanced open circuit voltage (V_{oc}) for the device 220 or 240. The enhanced V_{oc} originates from increased built-in potential of the device. Therefore, the band offset should be adjusted by adjusting the band gap of the p-type layer 222 or 252 to maximize stable efficiency after light soaking. In accordance with the present principles, band offset minimization between layers may be performed using one or more techniques.

Table I shows results for two different band offset adjustments. One band offset adjustment includes a 120 meV adjustment and the other adjustment, for a cell with a similar structure, includes an adjustment of 220 meV. The cell structure for the experimental results of Table I includes a 250 nm p-i-n stack and a ZnO electrode (e.g., TCO layer 201) connected to the p+ layer 222 or 252 on an opposite side of the intrinsic layer 224, 254. In Table I, a “before” state indicates the parameters before a 1.5 sun 32 hour light soaking to cause light induced degradation. This is referred to as an initial efficiency or state. An “after” state indicates the parameters after the 1.5 sun 32 hour light soaking to cause light induced degradation. This is referred to as a stable efficiency or state. The parameters of Table I include Efficiency (%), fill factor (FF) (%), open circuit voltage (V_{oc}) (in mV), short circuit current (J_{sc}) (in mA/cm²) and percent efficiency change (%). As can be seen in Table I, the efficiency change is less for the lower band offset change (e.g., 120 meV). Cells with the 120 meV offset yield a higher stable efficiency.

TABLE I

| p-layer to | | | | | | |
|---|---|---|---|---|---|---|
| intrinsic | | Effi- | Fill | | | % Effi- |
| layer offset | | ciency | Factor | V_{OC} | J_{SC} | ciency |
| (meV) | State | (%) | (%) | (mV) | (mA/cm²) | Change |
| 120 | Before | 9.24 | 72.16 | 861.90 | 14.85 | −11.70 |
| | After | 8.16 | 64.82 | 860.01 | 14.63 | |
| 220 | Before | 9.69 | 70.73 | 915.67 | 14.96 | −21.64 |
| | After | 7.59 | 57.16 | 901.07 | 14.74 | |

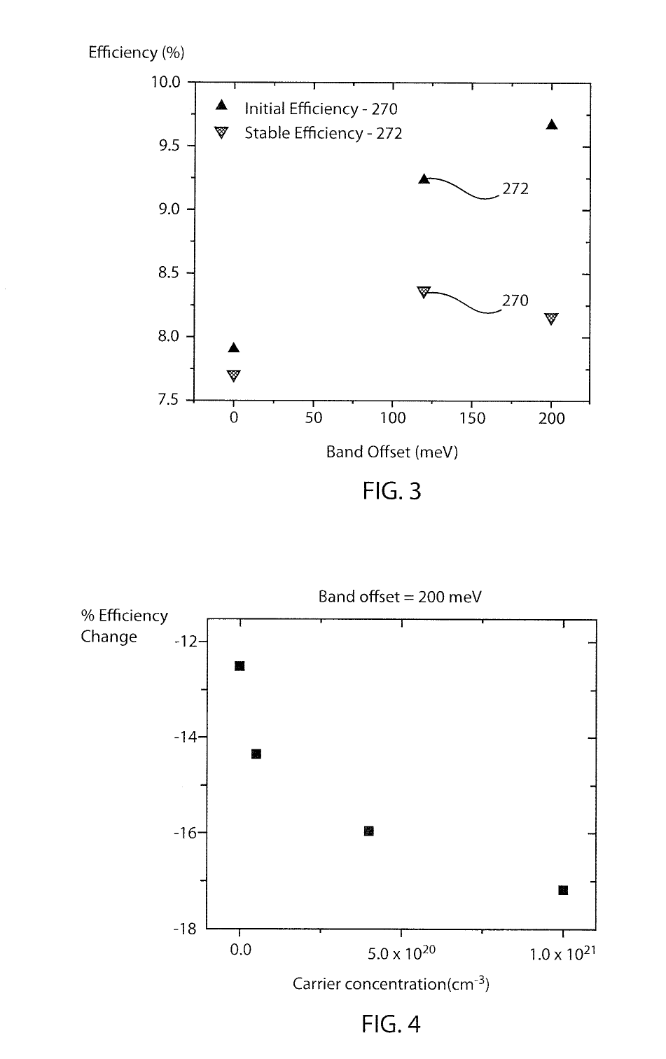

In FIG. 3, a band offset created by changing carbon content in the p-layer (222 of FIG. 1B) and increases in band offset with increasing carbon content are illustratively depicted. A plot 270 of initial efficiency is plotted with stable efficiency 272. As described above, initial efficiency increases with increased p-i band offset. However, stable efficiency does not follow efficiency enhancement with offset increase. Stable efficiency starts to saturate at about a 100-150 meV offset even if initial efficiency keeps increasing with greater offset.

Referring to FIG. 4, a graph shows efficiency change (%) versus carrier concentration (cm⁻³) at a transparent conductive oxide (TCO) (see e.g., TCO 201 in FIGS. 1A-1C) for a fixed p-i band offset of 200 meV in accordance with the present principles. In addition to the band offset at the p-i interface, there exists another band misalignment at the TCO/p+ interface, which increases with carrier concentration increase in the TCO (201). For less doped TCO layers, Fermi level of the TCO is closer to the valence band edge of the p+ a-Si:H layers. For higher doped TCO layers, the Fermi level is further from the valence band. Therefore, doping the TCO strongly affects band offset at the interface. Similar to the photo-degradation behavior of the p-i band offset, degradation increases with TCO/p+ band offset increases as shown in FIG. 4. Even after understanding that low doped TCO is desirable for high resistance to photo-degradation, highly doped TCO is desirable for a less resistive solar cell device.

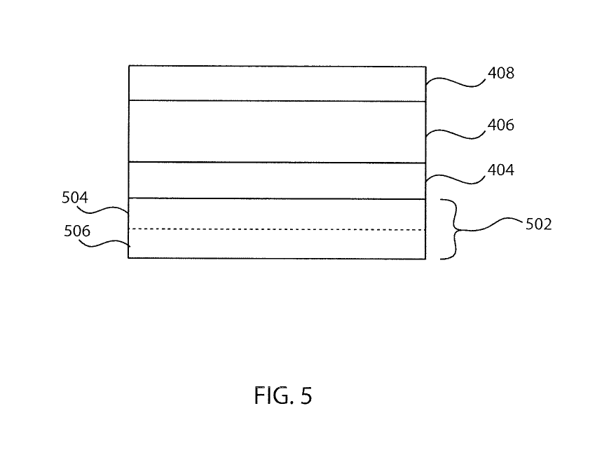

Referring to FIG. 5, a band offset is adjusted in accordance with the present principles to provide a degradation resistant photovoltaic device 500. As described, the process, materials and/or the carrier concentration may be adjusted by a plurality of different techniques. In one embodiment, a transparent electrode bi-layer 502 may be formed. The bi-layer 502 is an illustrative structure for a photovoltaic device 500. Other structures are also contemplated to reduce light-induced degradation. The device 500 includes a p-type layer 404, which may be adjusted using deposition temperature, C content, etc. or a combination thereof. An intrinsic layer 406 is formed on the p-type layer 404. The intrinsic layer 406 may preferably be undoped, although Ge content or other adjustments may also be made. An n-type layer 408 is formed on the intrinsic layer 406. In accordance with the present principles, the device 500 includes materials and processes which provide superior degradation resistance to light induced degradation.

The bi-layer 502 may include a base material, such as, ZnO and have a low (or no) carrier concentration layer 504 at an interface in contact with a p+ layer 404 and a higher carrier concentration layer 506 on the other side of the bi-layer electrode 502. It should be understood that the dopant concentration may be graded or graduated for bi-layer 502 with respect to distance from layer 404. The profile may be linear, exponential, stepped, etc.

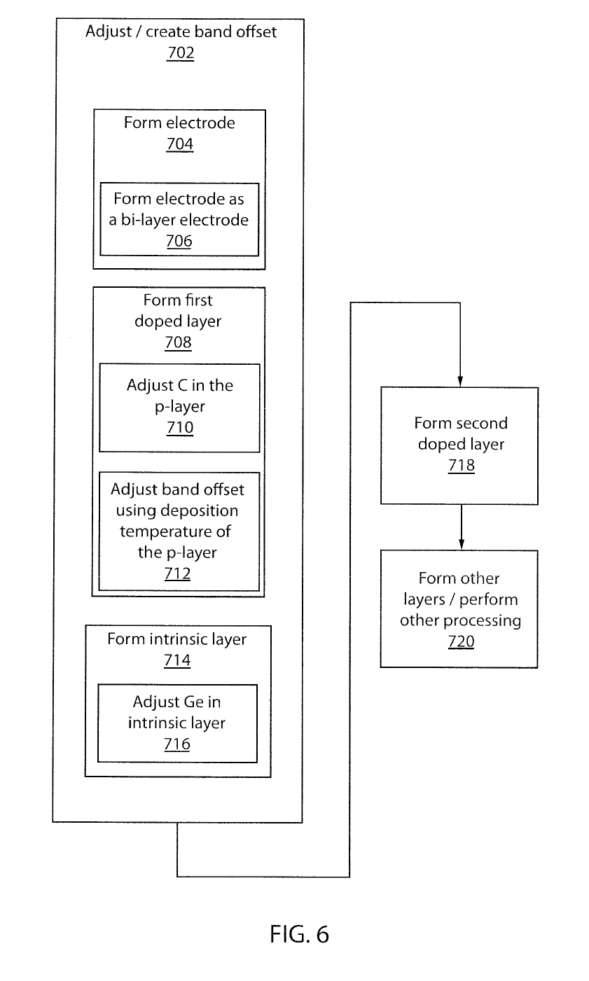

Referring to FIG. 6, a method for reducing degradation in a photovoltaic device is illustratively shown. It should also be noted that, in some alternative implementations, the functions noted in the block may occur out of the order noted. For example, two blocks shown in succession may, in fact, be executed substantially concurrently, or the blocks may sometimes be executed in the reverse order, depending upon the functionality involved. In block 702, a band offset of the photovoltaic device may be adjusted or created in the formation of or after the formation of several component layers. These may include the formation of a transparent electrode, a first doped layer and an intrinsic layer. The adjustment of the band offset results in resistance to light-induced degradation. In block 704, an electrode is formed. The electrode may be a transparent electrode, such as ZnO, indium tin oxide (ITO), etc. The electrode may be formed on other layers of a substrate depending on the device design. It should be understood that although the fabrication as described in this example includes an electrode with a p-i-n stack formed thereon, the device may be assembled in reverse order and/or be assembled using other fabrication techniques.

In block 706, the electrode may be formed to include a bi-layer electrode. The bi-layer electrode may include a highly doped portion opposite a lighter doped portion (or an undoped portion). The lighter doped portion is in contact with a first doped layer which is formed in contact therewith. The doping profile may be graduated, gradual, stepped, etc. The bi-layer electrode includes a low dopant concentration at an interface with the p-i-n stack so that band offset is minimized. Other portions of the bi-layer may have a higher dopant concentration to maintain conductivity.

In block 708, the first doped layer is formed for the p-i-n stack. The first doped layer is preferably a p-type layer although an n-type layer may be formed in accordance with other embodiments. In block 710, the band offset may include adjusting C content in the first doped layer formed from p-type amorphous silicon. In block 712, a deposition temperature of the first doped layer (e.g., a p-doped amorphous silicon) may be adjusted to reduce band offset.

In block 714, an intrinsic layer is formed on the first doped layer. In block 716, the band offset adjustment may include adjusting Ge content in the intrinsic layer formed from amorphous silicon.

In block 718, a second doped layer of the p-i-n stack is formed. In block 720, other structures or layers are formed to complete the device.

A band offset is created or adjusted during at least one of the steps of forming the electrode, forming the first doped layer, and forming the intrinsic layer (e.g., blocks 704, 708, 714) such that light induced degradation is reduced with lower band offset between one or more of the electrode, the first doped layer and the intrinsic layer. The creation or adjustment of the band offset may be achieved in any combination of the described methods.

Having described preferred embodiments of a reduction of light induced degradation by minimizing band offset (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method for reducing degradation in a photovoltaic device, comprising:
adjusting a band offset of the device during at least one of:
forming an electrode;
forming a first doped layer;
forming an intrinsic layer;
wherein the adjusting reduces the band offset between one or more of the electrode, the first doped layer and the intrinsic layer to reduce light-induced degradation of the device; and
forming a second doped layer on the intrinsic layer.

2. The method as recited in claim 1, wherein forming an electrode includes forming a bi-layer electrode.

3. The method as recited in claim 2, wherein the bi-layer electrode includes a highly doped portion opposite a lighter doped portion, the lighter doped portion being in contact with the first doped layer.

4. The method as recited in claim 1, wherein adjusting the band offset includes adjusting Ge content in the intrinsic layer formed from amorphous silicon.

5. The method as recited in claim 1, wherein adjusting the band offset includes adjusting C content in the first doped layer formed from p-type amorphous silicon.

6. The method as recited in claim 1, wherein adjusting the band offset includes adjusting a deposition temperature of the first doped layer formed from a p-doped amorphous silicon.

7. A method for reducing degradation in a photovoltaic device, comprising:
forming a bi-layer electrode by providing different dopant concentrations of the bi-layer electrode relative to a first doped layer to be formed thereon such that the bi-layer has a lower dopant concentration in contact with the first doped layer than other portions of the bi-layer electrode to reduce band offset between the bi-layer electrode and the first doped layer;
forming the first doped layer and an intrinsic layer on the first doped layer while adjusting a band offset between layers by adjusting dopant types and concentrations in at least one of the first doped layer and the intrinsic layer, such that light induced degradation is reduced with lower band offset between one or more of the bi-layer electrode, the first doped layer and the intrinsic layer; and
forming a second doped layer.

8. The method as recited in claim 7, wherein the bi-layer electrode includes a highly doped portion opposite a lighter doped portion, the lighter doped portion being in contact with the first doped layer.

9. The method as recited in claim 7, wherein adjusting the band offset includes adjusting Ge content in the intrinsic layer formed from amorphous silicon.

10. The method as recited in claim 7, wherein adjusting the band offset includes adjusting C content in the first doped layer formed from p-type amorphous silicon.

11. The method as recited in claim 7, wherein adjusting the band offset includes adjusting a deposition temperature of the first doped layer formed from a p-doped amorphous silicon.

12. A device having resistance to light-induced degradation, comprising:
a p-i-n stack having a p-type layer, an intrinsic layer and an n-type layer; and
a bi-layer transparent electrode in contact with the p-type layer and having a doping gradient which increases with distance from an interface between the p-type layer and the bi-layer transparent electrode, the bi-layer transparent electrode providing an interface having a reduced barrier offset to provide resistance to light-induced degradation.

13. The device as recited in claim 12, wherein the bi-layer electrode includes at least two dopant regions.

14. The device as recited in claim 13, wherein the at least two dopant regions include a highly doped region and a lighter region, the lighter doped region being in contact with the first doped layer.

15. The device as recited in claim 14, wherein the lighter doped region includes a concentration that provides approximately zero band offset between the lighter doped region and the p-type layer.

16. The device as recited in claim 14, wherein the highly doped region includes a concentration of about 1.0×10²¹ or less.

17. The device as recited in claim 12, wherein the intrinsic layer is formed from amorphous silicon and includes Ge content to adjust the band offset.

18. The device as recited in claim 12, wherein the p-type layer is formed from amorphous silicon and includes C content to adjust the band offset.

19. The device as recited in claim 12, wherein the bi-layer transparent electrode includes one of zinc oxide and indium tin oxide.

20. The device as recited in claim 12, wherein doping gradient includes a stepped dopant concentration.
